(19) United States
(12) Patent Application Publication
(10) Pub. No.: US 2007/0065976 A1
(43) Pub. Date: Mar. 22, 2007

(54) Method and apparatus for fabricating organic light emitting display device

(76) Inventors: Ji-Yong Lee, Yongin-si (KR); Won-Woong Jung, Yongin-si (KR); Hee-Cheol Kang, Yongin-si (KR)

Correspondence Address: Robert E. Bushnell, Suite 300, 1522 K Street, N.W., Washington, DC, 20005, US

(21) Appl. No.: 11/503,171

(22) Filed: Aug. 14, 2006

(30) Foreign Application Priority Data
Sep. 20, 2005 (KR) 2005-87424

(51) Int. Cl. H01L 51/40; H01L 29/08

(52) U.S. Cl. 438/99; 257/40

(57) ABSTRACT

A method and an apparatus for fabricating an organic light emitting display, in which a large-sized transmissible film is fabricated to be easily used in an affixing process for a large-sized substrate. The apparatus includes: a first chamber including a plurality of first through holes and having a first transmissible film sealing the plurality of first through holes, the first chamber adapted to affix a first substrate having an Organic Light Emitting Diode (OLED) to a second substrate having a desiccant agent; and a second chamber having a second through hole in a predetermined region and having a second transmissible film sealing the second through hole, the second chamber adapted to harden a sealant interposed between the first and second substrates to seal the first substrate to the second substrates.

### CLAIM OF PRIORITY

This application makes reference to, incorporates the same herein, and claims all benefits accruing under 35 U.S.C. § 119 from an application for FABRICA TING METHOD OF ORGANIC LIGHT EMITTING DISPLAY DEVICE AND FABRICATING APPARATUS OF THE SAME earlier filed in the Korean Intellectual Property Office on 20 Sep. 2005 and there duly assigned Serial No. 10-2005-0087424.

### BACKGROUND OF THE INVENTION

1 Field of the Invention

The present invention relates to fabricating an organic light emitting display, and more particularly, to a method and an apparatus for fabricating an organic light emitting display including forming a first substrate with an Organic Light Emitting Diode (OLED) and a second substrate for sealing the first substrate. An affixing process and a sealing process of the first and second substrates are performed separately.

2. Description of the Related Art

Recently, OLED displays using OLEDs have attracted attention. An OLED display is provided with a plurality of pixels, each including an OLED formed on a glass substrate, and a Thin Film Transistor (TFT) to drive the OLED. Such an OLED is susceptible to water, so that a sealing structure has been proposed for waterproofing, in which a deposition substrate is covered with a metal cap coated with a desiccant agent or a sealing glass substrate. In this sealing structure, a sealing process is performed by applying a load of a flat plate to a device glass substrate formed with the OLED and the sealing glass substrate or applying a uniform pressure of N₂ to an entire surface thereof.

A chamber for fabricating an organic light emitting display is used to perform both an affixing process for a first substrate and a second substrate and a hardening process for a sealant using ultraviolet (UV) light rays.

First, the first substrate is vacuum-affixed to a metallic suction plate opposite to a transmissible film, and the second substrate is placed on the transmissible film. An OLED formed in a predetermined area of the first substrate is opposite to a desiccant agent layer formed in a predetermined area of the second substrate.

Then, a transferring unit moves the suction plate down, and the transferring unit is pressed until the first substrate and the second substrate are spaced apart from each other by a predetermined gap, thereby applying a load to the suction plate or applying a uniform pressure of N₂ to an entire surface of the suction plate.

Then, a UV emitter provided outside of the chamber emits UV light rays to a sealant through the transmissible film and the second substrate. The sealant is then hardened, so that the first substrate and the second substrate are affixed to each other.

In the substrate sealing method described above, the transmissible film used in a process of hardening the sealant must endure the pressure of the affixing process and have a high UV transmissivity. Quartz, tempered glass, and hardened plastics satisfy these conditions and can be used as the transmissible film.

However, when the organic light emitting display using a large-sized substrate is in the affixing process, it is difficult to fabricate a transmissible film which maintains rigidity to endure the pressure, thereby limiting the affixing process of the large-sized substrate.

### SUMMARY OF THE INVENTION

Accordingly, it is an aspect of the present invention to provide a method and an apparatus for fabricating an organic light emitting display, in which a chamber for performing an affixing process of a large-sized substrate and a chamber for performing a UV-hardening process are provided separately to facilitate processing a large-sized transmissible film.

In an exemplary embodiment of the present invention, an apparatus for fabricating an organic light emitting display includes: a first chamber including a plurality of first through holes and having a first transmissible film sealing the plurality of first through holes, the first chamber adapted to affix a first substrate having an Organic Light Emitting Diode (OLED) to a second substrate having a desiccant agent; and a second chamber having a second through hole in a predetermined region and having a second transmissible film sealing the second through hole, the second chamber adapted to harden a sealant interposed between the first and second substrates to seal the first substrate to the second substrates.

The apparatus preferably further includes a transferring unit adapted to transfer the first and second substrates affixed to each other from the first chamber to the second chamber.

The first and second transmissible films each preferably include a film selected from a group consisting of quartz, tempered glass and hardened plastic.

The plurality of first through holes are preferably arranged in an outer circumference on a bottom of the first chamber. The plurality of first through holes are preferably arranged in at least six outer points on the bottom of the first chamber. The plurality of first through holes are preferably shaped like circles having a diameter in a range of 5 mm˜30 mm. The plurality of first through holes are alternatively preferably shaped like rectangles having a size of at least 5 mm×30 mm.

The second transmissible film is preferably divided into at least two parts together corresponding to a size of the first substrate.

The second through hole is preferably arranged on either a top or a bottom of the second chamber.

In another exemplary embodiment of the present invention, a method of fabricating an organic light emitting display includes: affixing a first substrate and a second substrate to each other in a first chamber having a plurality of first through holes and having a first transmissible film sealing the plurality of first through holes; exposing at least one region of the affixed first and second substrates to ultraviolet (UV) light rays; and applying a UV-hardening process to a sealant along a seal line of the first and second substrates in a second chamber having a second through hole in a predetermined region and having a second transmissible film sealing the second through hole.

Affixing the first and second substrates preferably includes aligning the first substrate and the second substrate and pressing the first substrate toward the second substrate.

### BRIEF DESCRIPTION OF THE DRAWINGS

A more complete appreciation of the present invention and many of the attendant advantages thereof will be readily apparent as the present invention becomes better understood by reference to the following detailed description when considered in conjunction with the accompanying drawings in which like reference symbols indicate the same or similar components, wherein:

FIG. 1 is a view of an organic light emitting display;

FIGS. 2A and 2B are respective views of a first chamber and a second chamber for an organic light emitting display according to an embodiment of the present invention;

FIG. 3A is an exploded perspective view of a coupled substrate and the first chamber according to an embodiment of the present invention;

FIG. 3B is an exploded perspective view of the coupled substrate and the second chamber according to an embodiment of the present invention; and

FIG. 4 is a flowchart of a method of fabricating the organic light emitting display according to an embodiment of the present invention.

### DETAILED DESCRIPTION OF INVENTION

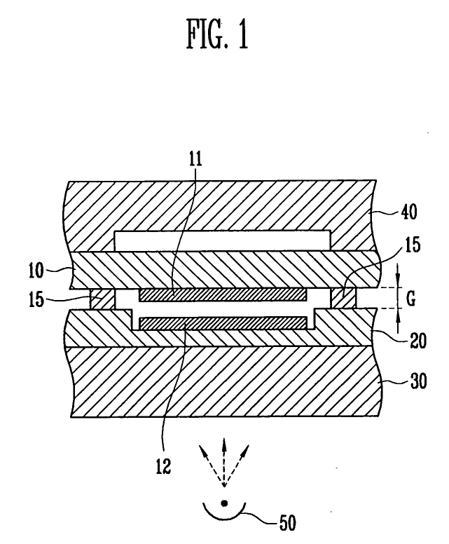

FIG. 1 is a view of an organic light emitting display fabricated in a chamber.

Referring to FIG. 1, a chamber (not shown) for fabricating the organic light emitting display is used to perform both an affixing process for a first substrate 10 and a second substrate 20 and a hardening process for a sealant using ultraviolet (UV) light rays.

First, the first substrate 10 is vacuum-affixed to a metallic suction plate 40 opposite to a transmissible film 30, and the second substrate 20 is placed on the transmissible film 30. An OLED 11 formed in a predetermined area of the first substrate 10 is opposite to a desiccant agent layer 12 formed in a predetermined area of the second substrate 20.

Then, a transferring unit (not shown) moves the suction plate 40 down, and the transferring unit is pressed until the first substrate 10 and the second substrate 20 are spaced apart from each other by a predetermined gap, thereby applying a load to the suction plate 40 or applying a uniform pressure of N₂ to an entire surface of the suction plate 40.

Then, a UV emitter 50 provided outside of the chamber (not shown) emits UV light rays to a sealant 15 through the transmissible film 30 and the second substrate 20. The sealant 15 is then hardened, so that the first substrate 10 and the second substrate 20 are affixed to each other.

In the substrate sealing method described above, the transmissible film 30 used in a process of hardening the sealant 15 must endure the pressure of the affixing process and have a high UV transmissivity. Quartz, tempered glass, and hardened plastics satisfy these conditions and can be used as the transmissible film 30.

However, when the organic light emitting display using a large-sized substrate is in the affixing process, it is difficult to fabricate a transmissible film 30 which maintains rigidity to endure the pressure, thereby limiting the affixing process of the large-sized substrate.

Hereinafter, exemplary embodiments of the present invention will be described with reference to accompanying drawings.

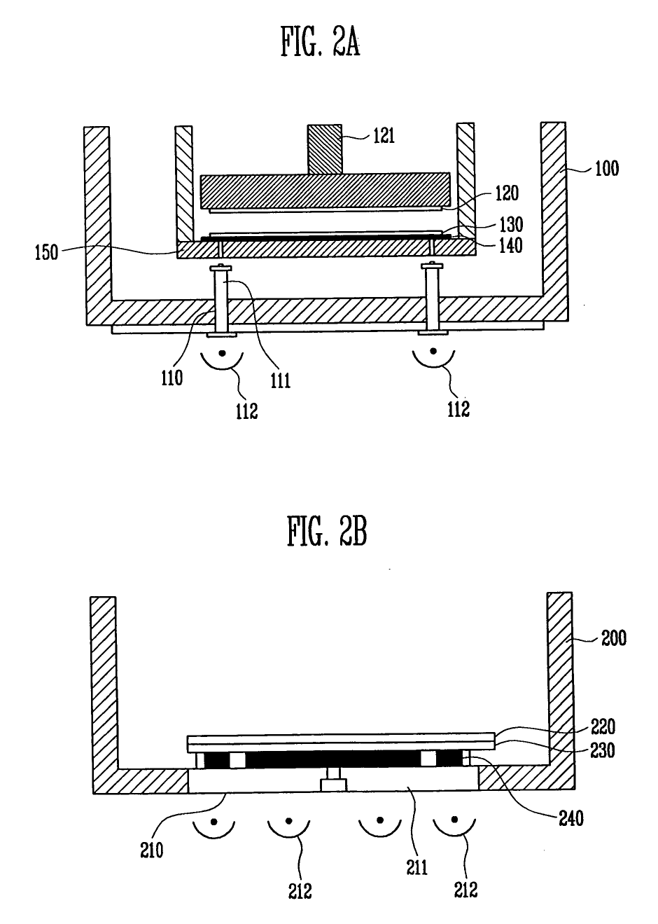

FIGS. 2A and 2B are respective views of a first chamber and a second chamber for an organic light emitting display according to an embodiment of the present invention.

Referring to FIGS.2A and 2B, an apparatus for an organic light emitting display according to an embodiment of the present invention performs a process of affixing a first substrate 120 and a second substrate 130 to each other in a first chamber 100, and then transfers the affixed first and second substrates 120 and 130 to the second chamber 200 by a transferring unit (not shown). Thereafter, a UV-hardening process is performed to seal the first substrate 120 to the second substrate 130.

First, in the first chamber 100, the first substrate 120 formed with an OLED (not shown) and the second substrate 130 used to seal the first substrate 120 are affixed to each other.

That is, the first substrate 120 is vacuum-affixed to a metallic suction plate 121 opposite to a first transmissible film 111, and the second substrate 130 is put on a mask 140.

The mask 140 is formed on a supporting plate 150 and used to prevent the UV light from having an effect on any region except a part corresponding to a sealant. The supporting plate 150 supports the first substrate 120, the second substrate 130 and the mask 140 to perform the affixing process for the first substrate 120 and the second substrate 130.

Then, the transferring unit moves the suction plate 121 down, and the transferring unit is pressed until the first substrate 120 and the second substrate 130 are spaced apart from each other by a predetermined gap, thereby applying a load to the suction plate 121 or applying a uniform pressure of N₂ to an entire surface of the suction plate 121.

The first chamber 100 is formed with a plurality of first through holes 110 in an outer circumference on the bottom thereof, and each first through hole 110 is sealed with the first transmissible film 111. At least six first through holes 110 are formed at outer points on the bottom of the first chamber 100. The shape of the first through hole 110 can be a circle having a diameter of 5 mm-30 mm, or a rectangle having a size of at least 5 mm×30 mm. Furthermore, the supporting plate 150 is formed with through holes having a predetermined size at positions corresponding to the first through holes 110, thereby allowing the UV light to pass through the supporting plate 150 and reach the sealant (not shown) between the first substrate 120 and the second substrate 130.

A UV emitter 112 is provided outside the first chamber 100. The UV light is directed by the UV emitter 112 to the sealant (not shown) between the first and second substrates 120 and 130 via the first transmissible film 111 to seal the plurality of first through holes 110.

Then, in the second chamber 200 performing the next process, a UV-hardening process is applied to the sealant in a seal line through a mask 240 in order to effect the entire adhesion between the first substrate 120 and the second substrate 130.

Furthermore, the second chamber 200 is formed with a second through hole 210 at a predetermined region on the bottom thereof, and the second through hole 210 is sealed with a second transmissible film 211. The second transmissible film 211 can be divided into at least two parts corresponding to the size of the first substrate 120. That is, because it is difficult to provide the second transmissible film 211 having a size corresponding to a large-sized substrate so that the UV light impinges on the substrate, the large-sized substrate is divided into predetermined regions and the second transmissible film 211 is placed in each region.

When a film growth surface of a circuit (not shown) formed on the coupled substrate is placed inside the seal line, the film growth surface of the circuit is not damaged even though the UV light impinges a top surface of the second chamber 200, so that the second through hole 210 can be formed on the top surface of the second chamber 200.

Furthermore, a UV emitter 212 is placed outside the second chamber 200. The UV emitter 212 directs the UV light to the sealant between the first and second substrates 120 and 130 via the second transmissible film 211 to sealing the plurality of second through holes 210. In the second chamber 200, the adhesion process between the first substrate 120 and the second substrate 130 is not performed, so that no pressure is applied to the second transmissible film 211. Thus, the UV-hardening process is performed without pressing the second transmissible film 211.

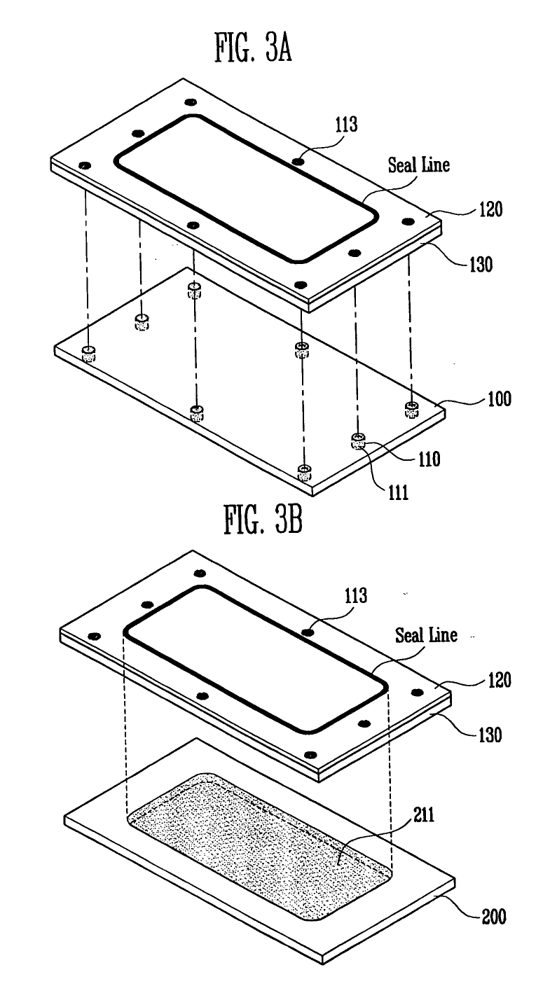

FIG. 3A is an exploded perspective view of a coupled substrate and the first chamber according to an embodiment of the present invention, and FIG. 3B is an exploded perspective view of the coupled substrate and the second chamber according to an embodiment of the present invention.

Below, the first substrate 120 and the second substrate 130 affixed to each other are referred to as a “coupled substrate”. Furthermore, the accompanying drawings show the bottoms of the first chamber 100 and the second chamber 200.

Referring to FIG. 3A and 3B, a plurality of spots 113 of the coupled substrate corresponding to the first through holes 110 of the first chamber 100 and the seal line are sealed with the sealant. When the coupled substrate is placed inside the first chamber 100, only the spots 113 are exposed to the UV light, so that the sealant in the spots 113 is hardened, thereby preventing misalignment between the first substrate 120 and the second substrate 130 when the coupled substrate moves from the first chamber 100 to the second chamber 200. As described above, when the UV-hardening process is applied to only the spots 113, the transmissible film 111 need not have a large area or thickness, so that the first transmissible film 111 is formed in the first through hole 110 through which the UV passes. Therefore, even though a load due to the adhesion process is generated in the first chamber 100, the first transmissible film 111 is not overstrained.

The first transmissible film 111 and the second transmissible film 211 respectively formed in the first chamber 100 and the second chamber 200 are made of a material having a high transmissivity to the UV. For example, the material includes quartz, tempered glass, and hardened plastics.

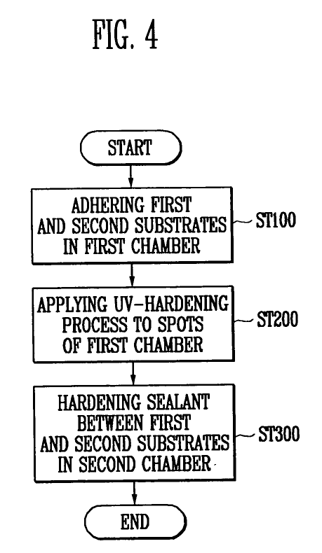

FIG. 4 is a flowchart of a method of fabricating the organic light emitting display according to an embodiment of the present invention.

Referring to FIG. 4, the organic light emitting display according to an embodiment of the present invention is fabricated by a first step ST100 through a third step ST300. In particular, the present invention relates to a fabricating method for an organic light emitting display that includes a first substrate formed with an OLED and a second substrate sealing the first substrate.

In the first step ST100, the first substrate and the second substrate are affixed to each other in a first chamber formed with a plurality of first through holes on the bottom thereof, in which the first through holes are sealed with a first transmissible film.

First, the first substrate is vacuum-affixed to a metallic suction plate opposite to the first transmissible film, and the second substrate is placed on the first transmissible film. The OLED formed in a predetermined region of the first substrate is arranged to face a desiccant agent layer formed in a predetermined region of the second substrate. Then, the transferring unit moves the suction plate down, and the transferring unit is suctioned until the first substrate and the second substrate are spaced apart from each other by a predetermined gap, thereby applying a load to the suction plate or applying a uniform pressure of N₂ to an entire surface of the suction plate.

In a second step ST200, spots of the coupled first and second substrates are exposed to UV light. That is, only the spots on the coupled substrate corresponding to the plurality of first through holes are exposed to UV light, thereby hardening a sealant of the spot, thereby preventing the misalignment between the first and second substrates when transferring the coupled first and second substrates from the first chamber to the second chamber in order to perform the following third step ST300.

In the third step ST300, a UV-hardening process is applied to the sealant along the seal line of the first and second substrates in the second chamber formed with second through holes in a predetermined region on the bottom thereof and having a second transmissible film sealing up the second through holes. Furthermore, the adhesion process between the first and second substrates is not performed in the second chamber, so that the second transmissible film is not pressed. Therefore, the UV-hardening process is performed without pressing the second transmissible film.

As described above, the adhesion process and the UV-hardening process according to an embodiment of the present invention are separately performed in different chambers as compared with the conventional technology in which the adhesion process and the UV-hardening process are performed in one chamber. Therefore, the transmissible film for UV-transmission need not receive pressure due to the adhesion process. Accordingly, the transmissible film becomes thin, thereby facilitating the process of the transmissible film.

Although exemplary embodiments of the present invention have been shown and described, it is understood that modifications can be made to these embodiments without departing from the principles and spirit of the present invention, the scope of which is defined by the appended claims.

What is claimed is:

1. An apparatus for fabricating an organic light emitting display, the apparatus comprising:
a first chamber including a plurality of first through holes and having a first transmissible film sealing the plurality of first through holes, the first chamber adapted to affix a first substrate having an Organic Light Emitting Diode (OLED) to a second substrate having a desiccant agent; and
a second chamber having a second through hole in a predetermined region and having a second transmissible film sealing the second through hole, the second chamber adapted to harden a sealant interposed between the first and second substrates to seal the first substrate to the second substrates.

2. The apparatus according to claim 1, further comprising a transferring unit adapted to transfer the first and second substrates affixed to each other from the first chamber to the second chamber.

3. The apparatus according to claim 1, wherein the first and second transmissible films each include a film selected from a group consisting of quartz, tempered glass and hardened plastic.

4. The apparatus according to claim 1, wherein the plurality of first through holes are arranged in an outer circumference on a bottom of the first chamber.

5. The apparatus according to claim 4, wherein the plurality of first through holes are arranged in at least six outer points on the bottom of the first chamber.

6. The apparatus according to claim 5, wherein the plurality of first through holes are shaped like circles having a diameter in a range of 5 mm 30 mm.

7. The apparatus according to claim 5, wherein the plurality of first through holes are shaped like rectangles having a size of at least 5 mm×30 mm.

8. The apparatus according to claim 1, wherein the second transmissible film is divided into at least two parts together corresponding to a size of the first substrate.

9. The apparatus according to claim 1, wherein the second through hole is arranged on either a top or a bottom of the second chamber.

10. A method of fabricating an organic light emitting display, the method comprising:
affixing a first substrate and a second substrate to each other in a first chamber having a plurality of first through holes and having a first transmissible film sealing the plurality of first, through holes;
exposing at least one region of the affixed first and second substrates to ultraviolet (UV) light rays; and
applying a UV-hardening process to a sealant along a seal line of the first and second substrates in a second chamber having a second through hole in a predetermined region and having a second transmissible film sealing the second through hole.

11. The method according to claim 10, wherein the affixing the first and second substrates comprises:
aligning the first substrate and the second substrate; and
pressing the first substrate toward the second substrate.
